(19) United States
(12) Patent Application Publication
(10) Pub. No.: US 2006/0125538 A1
(43) Pub. Date: Jun. 15, 2006

(54) Differential charge pump

(76) Inventor: Hooman Darabi, Irvine, CA (US)

Correspondence Address: CHRISTIE, PARKER & HALE, LLP, PO BOX 7068, PASADENA, CA, 91109-7068, US

(21) Appl. No.: 11/056,068

(22) Filed: Feb. 11, 2005

Related U.S. Application Data
(60) Provisional application No. 60/635,749, filed on Dec. 14, 2004.

(51) Int. Cl. H03L 7/06

(52) U.S. Cl. 327/157

(57) ABSTRACT

A charge pump may incorporate complementary NMOS and PMOS switches to charge and discharge an output capacitor. As a result, the UP and DOWN current paths may be symmetric in that each path incorporates PMOS and NMOS switches (e.g., transistors). The charge pump may incorporate “dummy” current paths for each of the UP and DOWN circuits. For example, when one of the circuits (e.g., UP or DOWN) is off, the corresponding “dummy” circuit may be turned on to maintain current flow from the associated current source. The charge pump may incorporate a unity gain buffer to maintain the proper current flow through the “dummy” stages. For example, the unity gain buffer may maintain an output node of the “dummy” circuits at substantially the same voltage level as an output node of the UP and DOWN circuits (e.g., the voltage level of the output capacitor).

### CROSS-REFERENCE TO RELATED APPLICATION(S)

This application claims the benefit of U.S. Provisional Patent Application No. 60/635,749, filed Dec. 14, 2004, the disclosure of which is hereby incorporated by reference herein.

### TECHNICAL FIELD

This application relates to electronic circuits and, more specifically, to charge pumps and associated components.

### BACKGROUND

A conventional charge pump is used to provide a desired charge on a capacitor such as a loop filter capacitor (e.g., in a phase lock loop circuit). The charge pump may be controlled by two input signals UP and DOWN. For example, when the charge on the capacitor needs to be increased the UP signal may be driven high and the DOWN signal may be driven low. Conversely, when the charge on the capacitor needs to be decreased the DOWN signal may be driven high and the UP signal may be driven low. Preferably, the UP and DOWN signals are symmetric.

Some conventional charge pumps may have undesirable nonlinearity characteristics that result from the use of different types of transistors. For example, some charge pumps may use a PMOS transistor to control current flow from a current source to the capacitor when the capacitor is being charged (UP is high). However, the charge pumps may use an NMOS transistor to control current flow from the capacitor to a current source when the capacitor is being discharged (DOWN is high).

Since these different types of transistors generally have different speed characteristics (e.g., NMOS has faster rise and fall times), the resulting switching times of these transistors times may be different. As a result, the symmetry of the signals that control the charge and discharge of the capacitor may be adversely affected. This, in turn, may create asymmetry problems in the loop. Accordingly, a need exists for an improved charge pump circuit.

### SUMMARY

The invention relates to charge pumps and associated components. For convenience, an embodiment of a system constructed or a method practiced according to the invention may be referred to herein simply as an “embodiment.”

In one aspect of the invention a charge pump incorporates complementary NMOS and PMOS switches to charge and discharge a reference capacitor. In other words, the UP and DOWN current paths are symmetric in that each path incorporates PMOS and NMOS switches (e.g., transistors).

In one aspect of the invention a charge pump incorporates “dummy” current paths for each of the UP and DOWN circuits. Here, when one of the circuits (e.g., UP or DOWN) is off, the corresponding “dummy” circuit may be turned on to maintain current flow from the associated current source. Conversely, when one of the circuits (e.g., UP or DOWN) is on, the corresponding “dummy” current path may be turned off. In this way, the charge on any capacitors associated with the current sources may be maintained at the proper level when the UP and DOWN signals are switched from one state to the other.

In one aspect of the invention a charge pump incorporates a unity gain buffer to maintain the proper current flow through the “dummy” stages. For example, the unity gain buffer may maintain an output node of the “dummy” circuits at substantially the same voltage level as an output node of the UP and DOWN circuits (e.g., the voltage level of the reference capacitor).

In some embodiments the unity gain buffer provides substantially rail-to-rail operation. For example, the unity gain buffer may incorporate a combination of NMOS and PMOS transistors to achieve rail-to-rail input common mode range.

### BRIEF DESCRIPTION OF THE DRAWINGS

These and other features, aspects and advantages of the present invention will be more fully understood when considered with respect to the following detailed description, appended claims and accompanying drawings, wherein:

FIG. 1 is a simplified block diagram of one embodiment of a charge pump constructed in accordance with the invention;

FIG. 2 is a flow chart of one embodiment of charge pump operations that may be performed in accordance with the invention;

FIG. 3 is a simplified schematic diagram of one embodiment of a charge pump constructed in accordance with the invention;

FIG. 4 is a simplified schematic diagram of one embodiment of a unity buffer constructed in accordance with the invention; and

FIG. 5 is a flow chart of one embodiment of unity buffer operations that may be performed in accordance with the invention.

In accordance with common practice the various features illustrated in the drawings may not be drawn to scale. Accordingly, the dimensions of the various features may be arbitrarily expanded or reduced for clarity. In addition, some of the drawings may be simplified for clarity. Thus, the drawings may not depict all of the components of a given apparatus or method. Finally, like reference numerals denote like features throughout the specification and figures.

### DETAILED DESCRIPTION

The invention is described below, with reference to detailed illustrative embodiments. It will be apparent that the invention may be embodied in a wide variety of forms, some of which may be quite different from those of the disclosed embodiments. Consequently, the specific structural and functional details disclosed herein are merely representative and do not limit the scope of the invention.

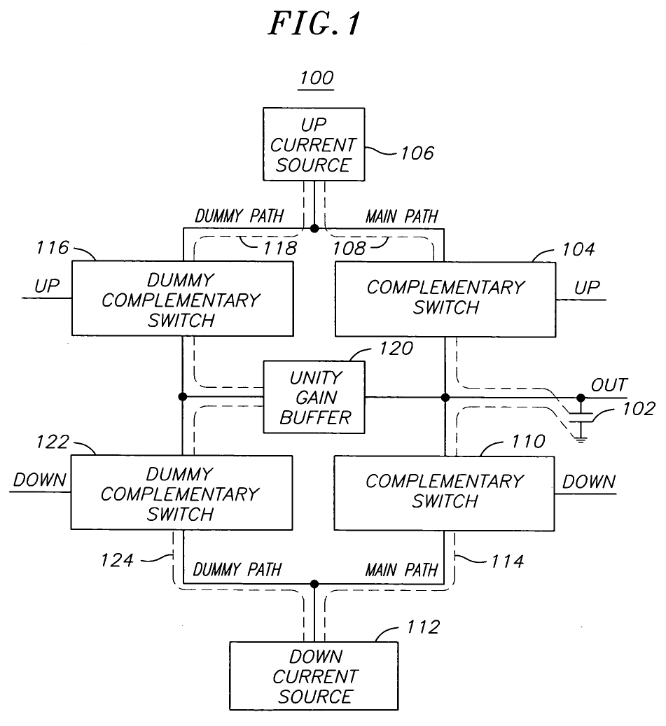

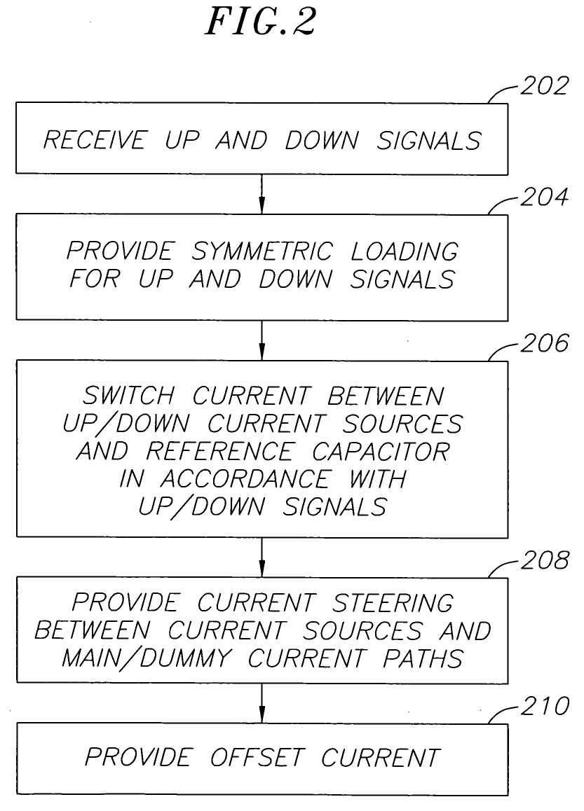

FIG. 1 is a simplified schematic block of one embodiment of a charge pump 100 constructed in accordance with the invention. The charge pump 100 charges and discharges a capacitor 102 according to the value of complementary UP and DOWN signals. One embodiment of operations that may be performed by a charge pump in accordance with the invention will be described in conjunction with the flow chart of FIG. 2.

As represented by block 202 in FIG. 2 the charge pump receives UP and DOWN signals from, for example, a phase detector (not shown) in a phase lock loop. In some embodiments each of the signals UP and DOWN may comprise differential signals.

The UP and DOWN signals control complementary switches 104 and 110, respectively. As represented by block 204, in some embodiments where the UP and DOWN signals are differential signals the complementary switches may provide symmetric current paths for the input signals. For example, in some embodiments both PMOS and NMOS transistors are used to switch current when the capacitor 102 is being charged and when the capacitor 102 is being discharged.

Block 206 represents the charge and discharge operations of the charge pump 100. The charge pump charges the capacitor when the UP signal is active (e.g., high) and the DOWN signal is inactive (e.g., low). In this state a complimentary switch 104 is switched on to allow current to flow from an up current source 106 to the capacitor 102 via a main up current path 108. Also during this state the complementary switch 110 is switched off to prevent current flow between a down current source 112 and the capacitor 102.

Conversely, the charge pump 100 discharges the capacitor 102 when the DOWN signal is active (e.g., high) and the UP signal is inactive (e.g., low). During this state the complimentary switch 110 allows current to flow via a main down current path 114 from the capacitor 102 to the down current source 112 to discharge the capacitor. During this state the complementary switch 104 is switched off to prevent current flow between the up current source 106 and the capacitor 102.

As represented by block 208 the charge pump 100 also provides a current steering mechanism to steer current to either a first current path (e.g., the main current paths 108 and 114) or to a second current path (e.g., the “dummy” current paths 118 and 124). The current steering mechanism enables the charge pump 100 to maintain current flow through the current sources 106 and 112 regardless of the state of the UP and DOWN signals. This is in contrast with conventional current sources that may, in effect, turn a current source off when the corresponding signal is inactive.

In this example a pair of “dummy” complementary switches 116 and 122 control current flow through the “dummy” current paths 118 and 124, respectively. For example, when a main current path (e.g., path 108) is switched off a corresponding “dummy” current path (e.g., path 118) is switch on and vice versa.

An output of a circuit capable of sourcing and sinking current (e.g., a unity gain buffer 120) provides a sink or source current for the “dummy” current paths 118 and 124. When a unity gain buffer 120 is used here, the output voltage of the buffer 120 is substantially the same as the input voltage (the OUT signal) of the buffer 120. As a result, the amount of current flowing through a “dummy” current path (e.g., path 124) will be substantially equal to the amount of current that flows through the corresponding main current path (e.g., path 114) when the states of the UP and DOWN signals change.

Through the use of the “dummy” complementary switches 116 and 122 and the unity gain buffer 120, capacitors (e.g., effective capacitance of transistors) in the current sources 106 and 112 may not be significantly charged or discharged when the UP and DOWN signals change states. As a result, additional current flow relating to the charging and discharging of the current source capacitors may not be caused to flow through the capacitor 102. This is in contrast with conventional charge pumps where current such as this which is unrelated to the duration of the UP and DOWN signals may flow through the reference capacitor, thereby adversely affecting the desired level of charge on the capacitor.

As represented by block 210, an optional current source (not shown in FIG. 1) may be used to provide an offset current for the capacitor 102. For example the optional current source may cause additional current to flow to the capacitor 102 to increase the charge on the capacitor 102. Alternatively, the optional current source may cause additional current to flow from the capacitor 102 to decrease the charge on the capacitor 102.

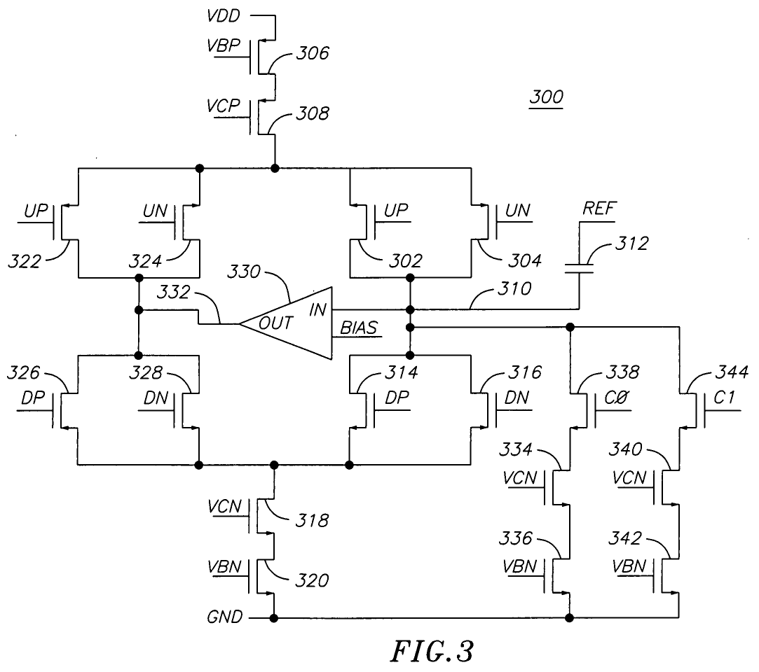

FIG. 3 is a simplified schematic diagram of one embodiment of a differential charge pump 300. The charge pump 300 is driven by a differential UP signal on leads UP and UN and by a differential DOWN signal on leads DP and DN.

The differential UP signal drives a transistor pair including transistors 302 and 304. This transistor pair controls the flow of current from an UP current source (e.g., transistors 306 and 308) to an output node 310 that connects to an output capacitor 312. In some embodiments the transistors 306 and 308 are implemented in a cascode configuration to improve the accuracy of the current source. The current provided by transistors 306 and 308 may be controlled by bias signals VBP and VCP.

The differential DOWN signal drives a transistor pair including transistors 314 and 316. This transistor pair controls the flow of current from the output capacitor 312 via the output node 310 to a DOWN current source (e.g., transistors 318 and 320). Again, in some embodiments the transistors 318 and 320 are implemented in a cascode configuration to improve the accuracy of the current source. The current provided by transistors 320 and 318 may be controlled by bias signals VBN and VCN.

When the UP differential signal is switched to the active state (e.g., UP is high and UN is low), transistors 302 and 304 will be turned on. In addition, the DOWN differential signal will be switched to an inactive state (e.g., DP is low and DN is high) at this time. Thus, transistors 314 and 316 will be turned off.

This condition will cause current to flow from the UP current source to the output capacitor 312 to charge the capacitor 312. Current will not flow from the capacitor 312 to the DOWN current source.

Conversely, when the DOWN differential signal is switched to the active state (e.g., DP is high and DN is low), transistors 314 and 316 will be turned on. In addition, the UP differential signal will be switched to an inactive state (e.g., UP is low and UN is high) at this time. Thus, transistors 302 and 304 will be turned off.

This condition will cause current to flow from the output capacitor 312 to the DOWN current source to discharge the capacitor 312. Current will not flow from the UP current source to the capacitor 312.

From the above it may be appreciated that both NMOS and PMOS transistors are used to switch the UP current on and off and to switch the DOWN current on and off. As a result, both of these paths will be substantially symmetric.

The charge pump also includes “dummy” paths for the UP and DOWN current. These “dummy” current paths serve to maintain the proper charges on the UP and DOWN current sources when the corresponding UP and DOWN switching transistors are turned off. For example, when transistors 302 and 304 are off, current would not normally flow from the UP current source. As a result, the internal capacitance of the transistors 306 and 308 may discharge. Consequently, when the transistors 302 and 304 are turned back on, the internal capacitance of the transistors 306 and 308 may need to be recharged. A similar scenario occurs for the DOWN path. This charging and discharging of the internal capacitors may have an adverse effect on the desired charging of the output capacitor 312. This, in turn, may cause nonlinearity in the circuit within which the charge pump is incorporated (e.g., a phase lock loop).

Accordingly, in accordance with one embodiment of the invention the charge pump 300 includes an UP “dummy” circuit including transistors 322 and 324, a DOWN “dummy” circuit including transistors 326 and 328 and a unity gain buffer 330.

The input connections to the “dummy” circuits are complementary to the input connections to the UP and DOWN switching transistors. In this way, the UP “dummy” circuit transistors 322 and 324 will be on when the UP switching transistors 302 and 304 are off and vice versa. Similarly, the DOWN “dummy” circuit transistors 326 and 328 will be on when the DOWN switching transistors 314 and 316 are off and vice versa. Thus, this configuration provides a current steering mechanism that enables the current sources to remain on at substantially all times.

Moreover, this configuration provides substantially identical loading on each of the input signals. For example, each of the UP and DOWN input signals (e.g., UP and UN, DP and DN) drives the same number of NMOS and PMOS transistors. This may further improve the symmetry of the loop circuit.

The unity gain buffer 330 maintains substantially the same voltage level at its output (node 332) as exists at its input (output node 310). Moreover, this may be accomplished without drawing appreciable current at its input (node 310). As a result, the unity gain buffer may not adversely affect the current flows to and from the capacitor 312.

The unity gain buffer 330 provides a source and a sink for current in the “dummy” paths. When the UP “dummy” circuit is on, current will flow from the UP current source through the transistors 322 and 324 to the unity gain buffer 330. Conversely, when the DOWN “dummy” circuit is on, current will flow from the unity gain buffer 330 through the transistors 326 and 328 to the DOWN current source.

Since the voltage level at the node 332 is maintained at the same level as the voltage at node 310, when an UP or DOWN signal becomes activated again, the associated current source will be providing the appropriate amount current for the newly activated UP or DOWN current path. As a result, the internal capacitors in the current source may not need to be charged or discharged when the UP and DOWN inputs to the charge pump change state.

In some embodiments the charge pump 300 includes one or more optional current sources that may be used to improve the linearity of the charge pump. Optional current sources may be incorporated into to the UP path and/or the DOWN path.

FIG. 3 illustrates one example where two optional current sources are provided in the DOWN path. A first optional current source includes transistors 334 and 336. The current from this current source may be added to the DOWN stage current when a transistor 338 is turned on by a control signal C0. The current provided by the transistors 334 and 336 is controlled by bias signals VCN and VBN or by other signals. Similarly, a second optional current source includes transistors 340 and 342. The current from this current source may be added to the DOWN stage current when a transistor 344 is turned on by a control signal C1. The current provided by the transistors 340 and 342 may be controlled by bias signals VCN and VBN or by other signals.

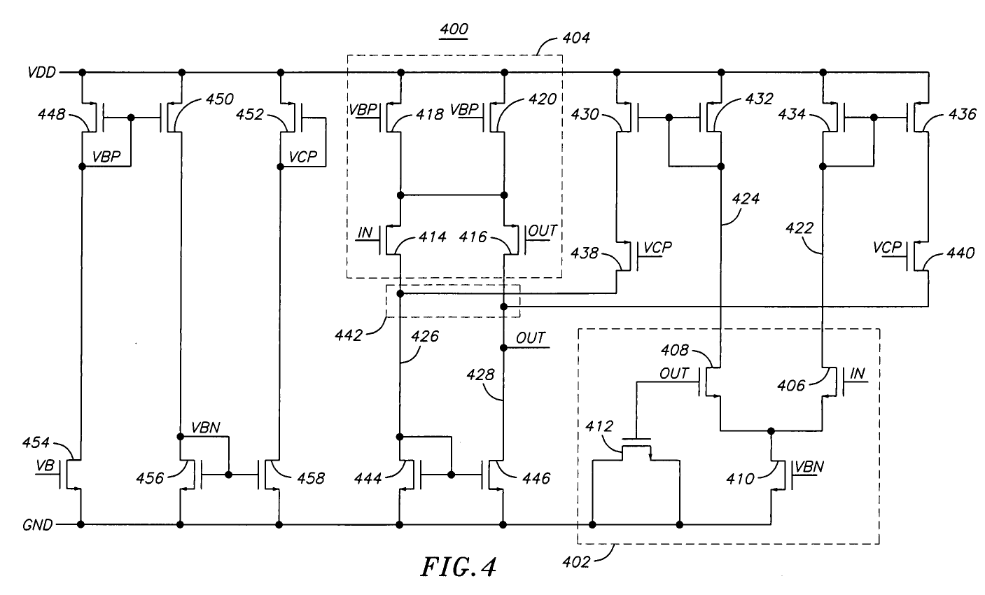

FIG. 4 is a simplified schematic diagram of one embodiment of a unity gain buffer 400 constructed in accordance with the invention. The buffer 400 incorporates both an NMOS input and a PMOS input (as represented by the dashed blocks 402 and 404, respectively) to achieve a rail-to-rail input common mode range and, consequently, a rail-to-rail output. Rail-to-rail operation may be desirable because the output (e.g., node 310 in FIG. 3) of the charge pump may typically be rail-to-rail. In other words, depending on the frequency at which a corresponding phase lock loop circuit locks, the output of the charge pump may be near either rail (e.g. VDD or GND, VDD or VSS, etc.).

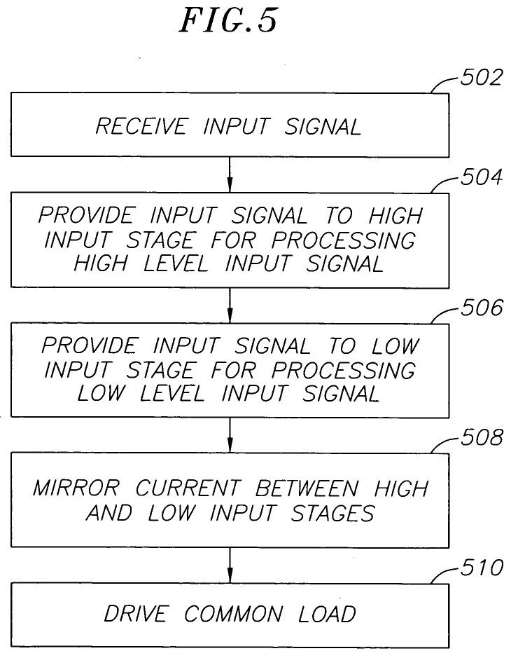

One embodiment of operations that may be performed by a buffer in accordance with the invention will be described in conjunction with the flow chart of FIG. 5. As represented by block 502 in FIG. 5 the buffer receives an input signal designated IN.

As represented by block 504 this IN signal is provided to an NMOS input stage 402 that is used to handle high level input signals (e.g., approximately ½VDD to approximately VDD). For example, the NMOS input 402 may be biased so that it will be on when the input signal IN is high and it will be off when the input signal IN is low.

The NMOS input 402 includes a differential transistor pair including transistors 406 and 408. The input signal IN drives the transistor 406. In the embodiment of FIG. 3, the signal IN would comprise the node 310. The input of the other transistor 408 is the fed back output signal OUT of the buffer. This is in accordance with a conventional unity gain amplifier configuration where the output of the amplifier is fed back to the “−” input of the amplifier. In some embodiments the current source for the differential pair consists of a transistor 410 driven by a bias signal VBN. A transistor 412 may provide some loading for the output signal OUT.

As represented by block 506 the IN signal is provided to a PMOS input stage 404 that is used to handle low level input signals (e.g., approximately GND to approximately ½VDD). For example, the PMOS input 404 may be biased so that it will be on when the input signal IN is low and it will be off when the input signal IN is high.

The PMOS input 404 includes a differential transistor pair including transistors 414 and 416. The input signal IN drives the transistor 414. The input of the other transistor 416 is the fed back output signal OUT. In some embodiments the current source for the differential pair consists of a pair of transistors 418 and 420 driven by a bias signal VBP.

As represented by block 508, the output (nodes 422 and 424) of the NMOS input stage 404 is coupled to the output (nodes 426 and 428) of the PMOS input stage 404 via a current mirror circuit. In FIG. 4 the current mirror circuit includes transistors 430, 432, 434, 436, 438 and 440. The outputs are thus combined at nodes 426 and 428 as represented by dashed block 442. An active single-ended load consisting of transistors 444 and 446 is provided for the output (block 510). In the embodiment of FIG. 3, the output signal OUT comprises node 332.

FIG. 4 also illustrates a bias circuit that generates bias signals VBN, VBP and VCP for the other transistors in the unity gain buffer 400 in accordance with a bias signal VB. Here, the bias circuit includes transistors 448, 450, 452, 454, 456 and 458.

The teachings of the invention may be incorporated into a variety of circuits. For example, the charge pump may be incorporated into a phase lock loop circuit, a delay lock loop circuit, etc.

It should be appreciated that the various components described herein may be incorporated in a circuit independently of the other components. For example, a circuit incorporating the teachings herein may include various combinations of these components. Thus, not all of the components described herein may be employed in every such circuit.

Moreover, a variety of components may be used in constructed a circuit in accordance with the invention. For example, different types of switches, current sources and sinks, buffers, transistors and circuit configurations may be used in such a circuit.

Different embodiments of the invention may be implemented using a variety of processes. For example, in some embodiments CMOS processes may be used to implement a circuit. However, it should be understood that other processes may be used to implement a circuit.

The components and functions described herein may be connected/coupled in many different ways. The manner in which this is done may depend, in part, on whether the components are separated from the other components. In some embodiments some of the connections represented by the lead lines in the drawings may be in an integrated circuit or on a circuit board.

The signals discussed herein may take several forms. For example, in some embodiments a signal may be an electrical signal transmitted over a wire. A signal may comprise more than one signal. For example, a signal may consist of a series of signals. Also, a differential signal comprises two complementary signals or some other combination of signals. Thus, a group of signals may be collectively referred to herein as a signal.

The components and functions described herein may be connected/coupled directly or indirectly. Thus, in some embodiments there may or may not be intervening devices (e.g., buffers) between connected/coupled components.

In summary, the invention described herein generally relates to an improved charge pump and associated components. While certain exemplary embodiments have been described above in detail and shown in the accompanying drawings, it is to be understood that such embodiments are merely illustrative of and not restrictive of the broad invention. In particular, it should be recognized that the teachings of the invention apply to a wide variety of systems and processes. It will thus be recognized that various modifications may be made to the illustrated and other embodiments of the invention described above, without departing from the broad inventive scope thereof. In view of the above it will be understood that the invention is not limited to the particular embodiments or arrangements disclosed, but is rather intended to cover any changes, adaptations or modifications which are within the scope and spirit of the invention as defined by the appended claims.

What is claimed is:

1. A charge pump for providing charge for a capacitor, the charge pump comprising:
an output node adapted to be coupled to the capacitor;
a plurality of current sources; and
a current steering circuit for steering current between the current sources and, in accordance with an UP input signal and a DOWN input signal, either a main current path circuit coupled to the current sources to provide source and sink current for the capacitor via the output node or a dummy current path circuit coupled to the current sources to source and sink current for the current sources.

2. The charge pump of claim 1 wherein the main current path circuit comprises a plurality of complementary switches.

3. The charge pump of claim 2 wherein the UP and DOWN input signals are differential signals and each complementary switch comprises PMOS and NMOS transistors configured to contemporaneously enable current flow in the main current path circuit in accordance with at least one of the UP and DOWN input signals.

4. The charge pump of claim 1 wherein the dummy current path circuit comprises a plurality of complementary switches.

5. The charge pump of claim 4 wherein the UP and DOWN input signals are differential signals and each complementary switch comprises PMOS and NMOS transistors configured to contemporaneously enable current flow in the dummy current path circuit in accordance with at least one of the UP and DOWN input signals.

6. The charge pump of claim 1 comprising a unity gain buffer for sourcing and sinking current in the dummy current path circuit.

7. The charge pump of claim 6 wherein an input of the unity gain buffer is coupled to the output node.

8. The charge pump of claim 6 wherein the unity gain buffer provides substantially rail-to-rail input common mode range.

9. The charge pump of claim 1 comprising a current source for providing an offset current at the output node.

10. A method of providing charge for a capacitor comprising:
receiving an UP input signal and a DOWN input signal;
providing current flow in a main current path between at least one current source and the capacitor in accordance with the UP input signal and the DOWN input signal; and
providing current flow in a dummy current path to and from the at least one current source in accordance with the UP input signal and the DOWN input signal.

11. The method of claim 10 comprising providing current steering such that the current flow in the main current path and the current flow in the dummy current path are substantially mutually exclusive.

12. The method of claim 10 wherein the UP and DOWN input signals are differential signals, the method comprising providing symmetric loading for the UP and DOWN input signals.

13. The method of claim 12 wherein the symmetric loading is provided by PMOS and NMOS transistors configured to contemporaneously enable current flow in the main current path in accordance with at least one of the UP and DOWN input signals.

14. The method of claim 12 wherein the symmetric loading is provided by PMOS and NMOS transistors configured to contemporaneously enable current flow in the dummy current path in accordance with at least one of the UP and DOWN input signals.

15. The method of claim 10 wherein providing current flow in the dummy current path comprises using a unity gain buffer to source and sink current.

16. The method of claim 10 wherein the unity gain buffer provides substantially rail-to-rail input common mode range.

17. The method of claim 10 comprising providing an offset current for the capacitor.

18. A charge pump for providing charge for a capacitor comprising:
an output node adapted to be coupled to the capacitor;
a buffer comprising an input coupled to the output node;
a first current source;
a first switch coupled to receive an UP input signal and configured to enable current flow between the first current source and the output node in accordance with a first state of the UP input signal;
a second switch coupled to receive the UP input signal and configured to enable current flow between the first current source and an output node of the buffer in accordance with a second state of the UP input signal;
a second current source;
a third switch coupled to receive a DOWN input signal and configured to enable current flow between the second current source and the output node in accordance with a first state of the DOWN input signal; and
a fourth switch coupled to receive the DOWN input signal and configured to enable current flow between the second current source and the output node of the buffer in accordance with a second state of the DOWN input signal.

19. The charge pump of claim 18 wherein each of the first and second switches comprise PMOS and NMOS transistors configured to contemporaneously enable current flow in the main current path in accordance with at least one of the UP and DOWN input signals.

20. The charge pump of claim 18 wherein each of the third and fourth switches comprise PMOS and NMOS transistors configured to contemporaneously enable current flow in the dummy current path in accordance with at least one of the UP and DOWN input signals.

21. The charge pump of claim 18 wherein the buffer comprises a unity gain buffer.

22. The charge pump of claim 21 wherein the unity gain buffer provides substantially rail-to-rail input common mode range.

23. The charge pump of claim 18 comprising a current source for providing an offset current at the output node.

24. A charge pump for providing charge for a capacitor comprising:
an output node adapted to be coupled to the capacitor;
a unity gain buffer comprising an input coupled to the output node;
a first current source;
a second current source;
a first pair of NMOS and CMOS transistors coupled to receive a differential UP input signal and coupled to the first current source and the output node;
a second pair of NMOS and CMOS transistors coupled to receive a differential DOWN input signal and coupled to the second current source and the output node;
a third pair of NMOS and CMOS transistors coupled to receive the differential UP input signal and coupled to the first current source and an output node of the unity gain buffer; and
a fourth pair of NMOS and CMOS transistors coupled to receive the differential DOWN input signal and coupled to the second current source and the output node of the unity gain buffer.

25. The charge pump of claim 24 wherein the current sources comprise cascode transistors.

26. The charge pump of claim 24 wherein the unity gain buffer provides substantially rail-to-rail input common mode range.

27. The charge pump of claim 24 comprising a current source for providing an offset current at the output node.

28. A unity gain buffer comprising:
a PMOS input stage coupled to receive an input signal;
an NMOS input stage coupled to receive the input signal;
a current mirror coupled to mirror output current of the PMOS and NMOS input stages; and
a load coupled to outputs of the PMOS and NMOS input stages.

29. The unity gain buffer of claim 28 wherein the PMOS input stage comprises a differential transistor pair.

30. The unity gain buffer of claim 28 wherein the PMOS input stage is activated when the input signal range is between about GND and about ½VDD.

31. The unity gain buffer of claim 28 wherein the NMOS input stage comprises a differential transistor pair.

32. The unity gain buffer of claim 28 wherein the NMOS input stage is activated when the input signal range is between about ½VDD and about VDD.

33. The unity gain buffer of claim 28 wherein the unity gain buffer provides substantially rail-to-rail input common mode range.
